(19) United States
(12) Patent Application Publication
(10) Pub. No.: US 2019/0210060 A1
(43) Pub. Date: Jul. 11, 2019

(54) MIST COATING FORMING APPARATUS AND MIST COATING FORMING METHOD

(71) Applicant: TOSHIBA MITSUBISHI-ELECTRIC INDUSTRIAL SYSTEMS CORPORATION, Chuo-ku (JP)

(72) Inventor: Tianming LI, Tokyo (JP)

(73) Assignee: TOSHIBA MITSUBISHI-ELECTRIC INDUSTRIAL SYSTEMS CORPORATION, Chuo-ku (JP)

(21) Appl. No.: 16/315,497

(22) PCT Filed: Jul. 11, 2016
(86) PCT No.: PCT/JP2016/070424

§ 371 Date: Jan. 4, 2019

(51) Int. Cl. B05D 1/02; B05B 7/26; B05B 17/06; B05D 7/24; B05D 3/02

(52) U.S. Cl. CPC B05D 1/02; B05B 7/26; C23C 16/4415; B05D 7/24; B05D 3/0254; B05B 17/06

(57) ABSTRACT

A raw material solution mist-forming mechanism forms a mist from a raw material solution, which is a nanoparticle dispersion or a nanofiber dispersion, and obtains a raw material solution mist. A mist coating mechanism coats the raw material solution mist to a surface of a substrate to form an extremely thin liquid film of the raw material solution on the substrate surface. A baking and drying mechanism bakes and dries, on a hot plate, the substrate on the surface of which the extremely thin liquid film of the raw material solution is formed and evaporates a solvent in the extremely thin liquid film of the raw material solution to form, on the substrate surface, a thin film containing, as a constituent material, a nanoparticle raw material or a nanofiber raw material contained in the extremely thin liquid film of the raw material solution.

### TECHNICAL FIELD

The present invention relates to a mist coating forming apparatus and a mist coating forming method for forming a mist from a raw material solution, which is a nanoparticle dispersion or a nanofiber dispersion, by using ultrasonic waves to form a thin film on a substrate subjected to film formation.

### BACKGROUND ART

One method of forming a metal oxide thin film from an organometallic compound under atmospheric pressure is a mist CVD film formation method.

The mist CVD film formation system is configured of two parts. One is a first part in which a mist is formed by using an ultrasonic transducer from a raw material solution in which an organometallic compound is dissolved to supply a raw material solution mist by a carrier gas. The other is a second part in which while the mist supplied by the carrier gas is sprayed from a film forming head onto a surface of a substrate, the raw material solution mist vaporized on the surface of the substrate reacts with an ozone oxidant or water vapor to form a metal oxide film.

The mist CVD film formation method is a method for forming a metal oxide thin film from a raw material solution in which an organometallic compound is dissolved through a chemical reaction. The CVD film forming methods are disclosed in, for example, Patent Document 1 and Non-Patent Document 1.

### PRIOR ART DOCUMENTS

### Patent Documents

Patent Document 1: Japanese Patent Application Laid-Open No. 2008-31541

### Non-Patent Documents

Non-Patent Document 1: T. Kawaharamura, “Physics on development of open-air atmospheric pressure thin film fabrication technique using mist droplets: Control of precursor flow,” Japanese Journal of Applied Physics, Vol. 53(05FF08), 2014.

### SUMMARY

### Problem to be Solved by the Invention

A conventional mist CVD film formation apparatus disclosed in Patent Document 1 or Non-Patent Document 1 forms a mist by using an ultrasonic transducer from a raw material solution in which an organometallic compound is dissolved, and the mist is transported to a film forming head by a carrier gas. The mist supplied from the film forming head is vaporized, and the raw material vaporized on the heated film forming substrate reacts with an oxidant to produce a metal oxide film.

Thus, the mist CVD film formation method is a method of forming a metal oxide film of zinc oxide, alumina, or the like from an organometallic compound such as diethyl zinc or aluminum acetylacetonate by using a chemical method.

However, in the conventional mist CVD film formation method, there is a problem that although a metal oxide thin film can be formed, a thin film having functionality such as a nanoparticle thin film or a nanofiber thin film cannot be formed from a raw material solution which is a nanoparticle dispersion or a nanofiber dispersion. In recent years, due to high performance of functional films, optical films, and flat display panels, needs for thin films having various functionalities have been increased, and the conventional mist CVD film formation method cannot meet the needs.

An object of the present invention is to solve the above problems and to provide a mist coating forming apparatus and a mist coating forming method that can form a thin functional film other than a metal oxide film.

### Means to Solve the Problem

A mist coating forming apparatus according to the present invention includes: a raw material solution mist-forming mechanism configured to form a mist from a raw material solution in an atomization container by using an ultrasonic transducer to obtain a raw material solution mist in a form of droplets, the raw material solution being a nanoparticle dispersion or a nanofiber dispersion containing a predetermined raw material; a mist coating mechanism including a mounting part on which a substrate subjected to film formation is mounted, and configured to supply the raw material solution mist to the substrate, to coat the raw material solution mist to a surface of the substrate, and to form a liquid film of the raw material solution on the surface of the substrate; and a baking and drying mechanism configured to bake and dry the liquid film of the raw material solution formed on the surface of the substrate to form, on the surface of the substrate, a thin film containing as a constituent material the predetermined raw material contained in the liquid film of the raw material solution.

### Effects of the Invention

The mist coating forming apparatus of the present invention according to claim 1 coats a raw material solution mist by a mist coating mechanism to form a liquid film of a raw material solution on a surface of a substrate and then bakes and dries the liquid film of the raw material solution by a baking and drying mechanism to form a thin film containing a predetermined raw material on the surface of the substrate. In this case, a nanoparticle dispersion or a nanofiber dispersion is used as the raw material solution.

As a result, the mist coating thrilling apparatus of the present invention according to claim 1 can form, on the surface of the substrate, a thin film containing as a constituent material the predetermined raw material contained in the nanoparticle dispersion or the nanofiber dispersion with high uniformity.

The objects, features, aspects, and advantages of the present invention will become more apparent from the following detailed description and the accompanying drawings.

### BRIEF DESCRIPTION OF DRAWINGS

FIG. 1 is an explanatory view schematically showing a configuration of a mist coating forming apparatus according to an embodiment of the present invention.

FIG. 2 is a plan view showing a bottom structure of a mist coating head shown in FIG. 1.

FIG. 3 is a flowchart showing a film formation procedure of a mist coating forming method implemented using the mist coating forming apparatus shown in FIG. 1.

FIG. 4 is an explanatory view schematically showing conditions on the surface of the substrate upon implementation of the mist coating forming method according to the present embodiment.

FIG. 5 is an explanatory view schematically showing a positional relationship of a head bottom surface relative to the substrate.

FIG. 6 is a view showing an image of a formed nanofiber thin film observed with a SEM.

### DESCRIPTION OF EMBODIMENTS

Hereinafter, an embodiment of the present invention will be described with reference to the drawings.

### Embodiment 1

(Mist Coating Forming Apparatus)

FIG. 1 is an explanatory view schematically showing a configuration of a mist coating forming apparatus according to an embodiment of the present invention. As shown in FIG. 1, the mist coating forming apparatus of Embodiment 1 has a raw material solution mist-forming mechanism 50, a mist coating mechanism 70 and a baking and drying mechanism 90 as main components.

The raw material solution mist-forming mechanism 50 implements raw material solution mist generating processing for using an ultrasonic transducer 1 generating ultrasonic waves to form a mist from (atomize) a raw material solution 5 in an atomization container 4 in a form of droplets having a narrow particle size distribution and a central particle size of about 4 μm and to generate a raw material solution mist 6. The raw material solution mist 6 is transported to the mist coating mechanism 70 via a mist supply line 22 by a carrier gas supplied from a carrier gas supply part 16.

The mist coating mechanism 70 implements raw material solution mist coating processing for receiving the raw material solution mist 6 from the mist supply line 22, supplying the raw material solution mist 6 from a mist coating head 8 to the surface of the substrate 9 (substrate subjected to film formation) mounted on a moving stage 10 (mounting part), coating the raw material solution mist 6 to the surface of a substrate 9, and forming an extremely thin liquid film of the raw material solution (liquid film of raw material solution) on the surface of the substrate 9.

The baking and drying mechanism 90 implements baking and drying processing for baking and drying, on a hot plate 13, the substrate 9 on the surface of which a thin liquid film of the raw material solution is formed, evaporating a solvent in the extremely thin liquid film of the raw material solution, and forming, on the surface of the substrate 9, a thin film containing as a constituent material a nanoparticle raw material or a nanofiber raw material contained in the extremely thin liquid film of the raw material solution.

(Raw Material Solution Mist-Forming Mechanism 50)

In the raw material solution mist-forming mechanism 50, an ultrasonic frequency within the range of 1.5 to 2.5 MHz, for example, can be used for the ultrasonic transducer 1. Water 3 is introduced as a medium for ultrasonic wave propagation generated by the ultrasonic transducer 1 to a water tank 2 provided above the ultrasonic transducer 1, and by driving the ultrasonic transducer 1, the raw material solution 5 in the mist formation container 4 is formed into a mist (atomized) to obtain the raw material solution mist 6 of micrometer-sized droplets having a narrow particle size distribution and a central particle size of about 4 μm.

As the raw material solution 5, a raw material solution which is diluted with a solvent with low viscosity such as methanol, toluene, water, hexane, ether, methyl acetate, ethyl acetate, vinyl acetate, or ethyl chloride, and has a viscosity of 1.1 mPa·s or less even if the viscosity of the raw material solution is high is assumed.

A case where the raw material solution 5 is a nanoparticle dispersion will be considered. In this case, for example, a silver nanoparticle dispersion, a zirconium oxide dispersion, a cerium oxide dispersion, an indium oxide dispersion, a tin oxide dispersion, a zinc oxide dispersion, a titanium oxide dispersion, a silica dispersion or an alumina dispersion is considered. These dispersions are diluted with the above solvent to obtain the raw material solution 5.

Therefore, the nanoparticle raw material (predetermined raw material) contained in the above-described nanoparticle dispersion is a silver nanoparticle, a zirconium oxide nanoparticle, a cerium oxide nanoparticle, an indium oxide nanoparticle, a tin oxide nanoparticle, a zinc oxide nanoparticle, a titanium oxide nanoparticle, a silica nanoparticle, or an alumina nanoparticle.

A “nanoparticle” means a particle having a particle size of 100 nm or less, and a “nanoparticle dispersion” means that a nanoparticle exists in a floating state without being dissolved in a solvent such as water or alcohol.

On the other hand, a case where the raw material solution 5 is a nanofiber dispersion will be considered. In this case, for example, a carbon nanotube dispersion, a silver nanofiber dispersion, or a cellulose nanofiber dispersion is considered, and these dispersions are diluted with the above solvent to obtain the raw material solution 5.

The nanofiber raw material (predetermined raw material) contained in the above-described nanofiber aqueous dispersion is a carbon nanotube, a silver nanofiber, or a cellulose nanofiber.

A “nanofiber” means a fibrous material having a fiber diameter of 100 nm or less, and a “nanofiber dispersion” means that a nanofiber exists in a floating state without being dissolved in a solvent such as water or alcohol.

By supplying the carrier gas supplied from the carrier gas supply part 16 from a carrier gas introduction line 21 into the mist formation container 4, the raw material solution mist 6, which is in the form of droplets, formed into a mist in the internal space of the mist formation container 4 is transported toward the mist coating head 8 of the mist coating mechanism 70 via the mist supply line 22. Nitrogen gas or air is mainly used as the carrier gas for the purpose of transporting the raw material solution mist 6, and a carrier gas flow rate is controlled so as to be 2 to 10 (L/min) by a mist controller 35. Note that, a valve 21b is disposed in the carrier gas introduction line 21 and is a valve for adjusting the carrier gas flow rate.

The mist controller 35 controls the carrier gas flow rate of the carrier gas supplied from the carrier gas supply part 16 by controlling the degree of opening and closing of the valve 21b, and controls the presence/absence of vibration of the ultrasonic transducer 1, the ultrasonic frequency, and the like.

(Mist Coating Mechanism 70)

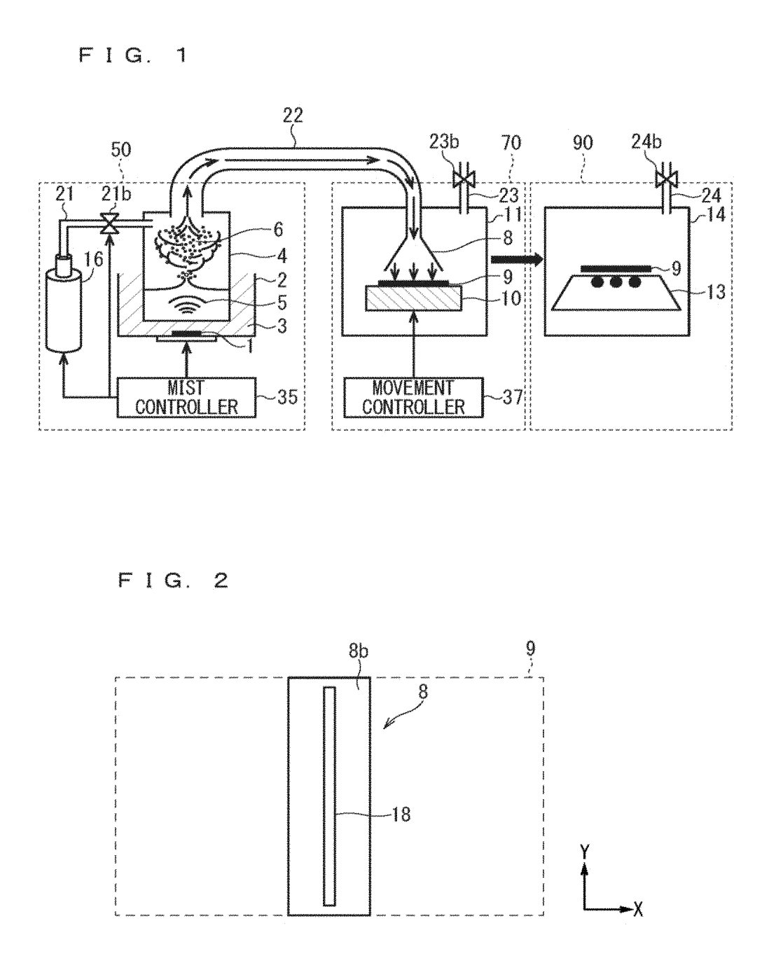

The mist coating mechanism 70 has, as main components, the mist coating head 8 and a moving stage 10 (mounting part) which is movable with the substrate 9 subjected to film formation mounted thereon under the control of the movement controller 37.
FIG. 2 is a plan view showing a bottom structure of the mist coating head 8. The XY coordinate axes are shown in FIG. 2. As shown in FIG. 2, a mist ejection port 18 of a slit shape in which the Y direction (predetermined direction) is a longitudinal direction is formed in a head bottom surface 8b of the mist coating head 8.

In FIG. 2, a hypothetical plane position or the substrate 9 existing under the head bottom surface 8b of the mist coating head 8 is shown. The substrate 9 is configured in a rectangular shape in which a side in the X direction is a long side and a side in the Y direction is a short side.

As shown in FIG. 2, the mist ejection port 18 provided in the head bottom surface 8b is provided in a slit shape in which the short side forming direction (Y direction) of the substrate 9 is the longitudinal direction, and its forming length (Y direction length) is set to be approximately equal to a short side width of the substrate 9.

Therefore, for example, by supplying the raw material solution mist 6 straightened in the mist coating head 8 from the mist ejection port 18 while moving the substrate 9 along the X direction (transverse direction of the mist ejection port 18) by the moving stage 10, it is possible to coat (he raw material solution mist 6 to almost the entire surface of the substrate 9, and to form the extremely thin liquid film of the raw material solution on the surface of the substrate 9. In addition, since the mist ejection port 18 is formed in a slit shape, by adjusting the forming length in the longitudinal direction (Y direction, predetermined direction) of the mist coating head 8, the forming length of the mist ejection port can also be adapted to the substrate 9 having a wide short-side width without being limited by the short side width of the substrate 9 which is a substrate subjected to film formation. Specifically, by providing the mist coating head 8 with a width in the longitudinal direction matching the assumed maximum short-side width of the substrate 9, the forming length of the mist ejection port 18 can be made substantially equal to the maximum short-side width of the substrate 9.

Note that, when the moving stage 10 on which the substrate 9 is mounted on the upper side moves along the X direction in a state of being 1 to 5 mm away from the head bottom surface 8b of the mist coating head 8 under the control of the movement controller 37. it is possible to coat the extremely thin liquid film of the raw material solution to the surface of the substrate 9 by coating the raw material solution mist 6 to almost the entire surface of the substrate 9.

At this time, the thickness of the extremely thin liquid film of the raw material solution can be adjusted by changing the moving speed of the moving stage 10 by the movement controller 37.

That is, the movement controller 37 moves the moving stage 10 along a moving direction (X direction in FIG. 2) which matches the transverse direction of the mist ejection port 18 of the mist coating head 8, and variably controls the moving speed of the moving stage 10 along the moving direction.

The mist coating head 8 and the moving stage 10 are disposed in a mist coating chamber 11, and a mixed gas of a solvent vapor of the raw material solution mist 6 evaporated in the mist coating chamber 13 and the carrier gas flows through an exhaust gas output line 23, is treated by an exhaust treatment device (not shown), and is then released to the atmosphere. A valve 23b is a valve provided in the exhaust gas output line 23.

(Baking and Drying Mechanism 90)

The baking and drying mechanism 90 has the hot plate 13 provided in a baking-drying chamber 14 as a main component. The substrate 9 on the surface of which the extremely thin liquid film of the raw material solution is formed by coating the raw material solution mist 6 by the mist coating mechanism 70 is mounted on the hot plate 13 in the baking-drying chamber 14.

By performing the baking and drying processing on the substrate 9 on the surface of which the extremely thin liquid film of the raw material solution is formed by using the hot plate 13, it is possible to evaporate the solvent in the extremely thin liquid film of the raw material solution formed by coating the raw material solution mist 6 and to form, on the surface of the substrate 9, a thin film containing as a constituent material the raw material (predetermined raw material) itself contained in the raw material solution 5. That is, the thin film has a smaller thickness than that of the extremely thin liquid film of the raw material solution, and the composition thereof is identical to the composition of the raw material solution 5. A solvent vapor of the raw material solution 5 produced by the baking and drying processing is discharged to the atmosphere from an exhaust gas output line 24 after being treated by an exhaust treatment device (not shown).

Note that, in the example shown in FIG. 1, the baking and drying processing is implemented using the hot plate 13; however, the baking and drying mechanism 90 may be configured in an aspect in which hot air is supplied into the baking-drying chamber 14 without using the hot plate 13.

(Mist Coating Forming Method)

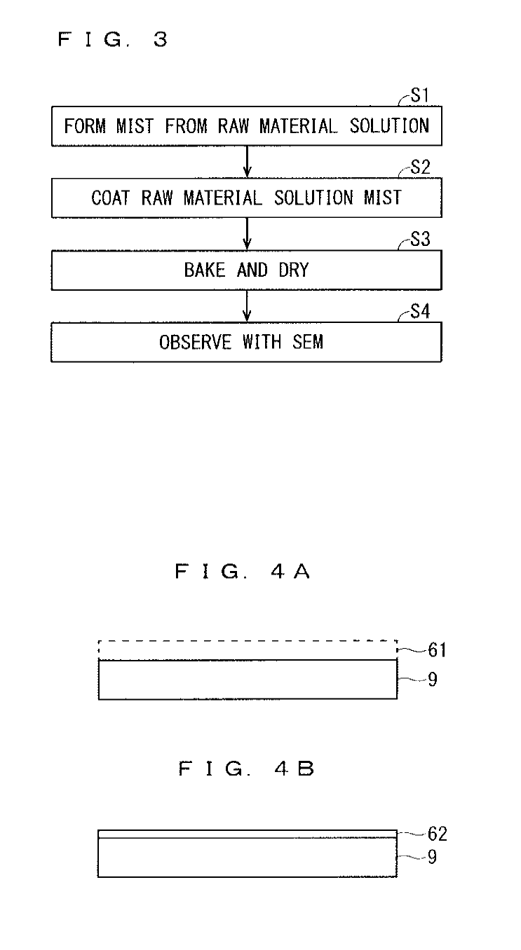

FIG. 3 is a flowchart showing a film formation procedure of a mist coating forming method implemented using the mist coating forming apparatus shown in FIG. 1. FIG. 4 is an explanatory view schematically showing conditions on the surface of the substrate 9 upon implementation of the mist coating forming method. Hereinafter, with reference to FIGS. 3 and 4, the processing procedure of the mist coating forming method will be described.

In step S1, the raw material solution mist-forming mechanism 50 implements the raw material solution mist generating processing for using the ultrasonic transducer 1 to form a mist from the raw material solution 5 in the atomization container 4 and to generate the raw material solution mist 6 in the form of droplets. Hereinafter, a case where a nanofiber dispersion is used as the raw material solution 5 will be described.

Specifically, a nanofiber dispersion of 1 wt % (weight percent) is diluted so as to have a viscosity of 1.1 mPa·s or less to obtain the raw material solution 5. Two ultrasonic transducers 1 (only one ultrasonic transducer 1 is shown in FIG. 1) oscillating at 1.6 MHz are driven to form a mist from the raw material solution 5, and the raw material solution mist 6 generated in the mist formation container 4 can be transported to the mist coating head 8 in the mist coating mechanism 70 via the mist supply line 22 by supplying a nitrogen carrier gas whose carrier gas flow rate is 2 L/min from the carrier gas supply part 16.

As described above, by controlling the number of operating transducers in the plurality of ultrasonic transducers 1 and the carrier gas flow rate in the carrier gas supplied from the carrier gas supply part 16 under the control of the mist controller 35, which is an atomization controller, it is possible to supply the raw material solution mist 6 to the mist coating head 8 of the mist coating mechanism 70 with high accuracy.

Next, in step S2, the mist coating mechanism 70 implements the raw material solution mist coating processing for mounting the substrate 9 subjected to coating on the moving stage 10, supplying the raw material solution mist 6 from the mist ejection port 18 of the mist coating head 8, coating the raw material solution mist 6 to the surface of the substrate 9, and forming the extremely thin liquid film 61 of the raw material solution (liquid film of the raw material solution) on the surface of the substrate 9 as shown in FIG. 4(a).

Specifically, the raw material solution mist 6 straightened in the mist coating head 8 is supplied to the surface of the substrate 9 through the mist ejection port 18 formed in a slit shape, and thereby the raw material solution mist coating processing is implemented. The substrate 9 has a rectangular surface having the long side of 400 (mm) and the short side of 200 (mm).

The substrate 9 mounted (set) on the moving stage 10 is present at a distance of 1 to 5 mm below the head bottom surface 8b, and under the control of the movement controller 37, the moving stage 10 is moved (scanned) in the X direction in FIG. 2, and thereby, the extremely thin liquid film 61 of the raw material solution is formed by coating the raw material solution mist 6 to almost the entire surface of the substrate 9. The moving speed of the moving stage 10 can be variably controlled by the movement controller 37 within the range of 1 to 50 (mm/sec).

In order to coat the raw material solution mist 6 to form the extremely thin liquid film 61 of the raw material solution on the surface of the substrate 9, it is necessary that the raw material solution mist 6 wets well the surface of the substrate 9 (to improve wettability). In order for the raw material solution mist 6 to wet well the surface of the substrate 9, it is necessary to increase the surface tension of the substrate 9 by reducing the surface tension of the raw material solution mist 6. Since the raw material solution 5 is a nanofiber dispersion, by using methanol as a solvent water to reduce the surface tension of the raw material solution mist 6, and by removing organic substances and metal substances which become dirt on the surface of the substrate 9, the surface tension of the substrate 9 is increased. As a result, wettability of the raw material solution mist 6 to be coated on the surface of the substrate 9 is increased, and therefore, it is possible to form the extremely thin liquid film 61 of the raw material solution in a liquid state on the surface of the substrate 9.

In this way, by using a solvent having a low surface tension in the raw material solution 5 and by removing surface dirt of the substrate 9, the raw material solution mist 6 to be coated wets well the surface of the substrate 9 to form the extremely thin liquid film 61 of the raw material solution. In addition, by moving only the moving stage 10 on which the substrate 9 is mounted while fixing the mist coating head 8 to coat the raw material solution mist 6 to the surface of the substrate 9, the extremely thin liquid film 61 of the raw material solution can be relatively easily formed on the surface of the substrate 9.

FIG. 5 is an explanatory view schematically showing a positional relationship of the head bottom surface 8b relative to the substrate 9. In FIG. 5, the XZ coordinate axes are also shown. As shown in FIG. 5, by providing the head bottom surface 8b of the mist coating head 8 with an inclination θ with respect to the surface forming direction (X direction in FIG. 5) of the substrate 9, it is possible to eject the raw material solution mist 6 in the oblique direction by the angle θ from a perpendicular line L9 of the substrate 9 from the mist ejection port 18.

By providing the head bottom surface 8b of the mist coating head 8 with the inclination θ with respect to the surface forming direction of the substrate 9 as described above, it is possible to effectively suppress the turbulence of the liquid film caused at the time when the raw material solution mist 6 strikes the surface of the substrate 9 due to the flow rate of the carrier gas supplied from the carrier gas supply part 16, to coat the raw material solution mist 6 more uniformly to the surface of the substrate 9, and to increase uniformity of the extremely thin liquid film 61 of the raw material solution.

Next, in step S3, the baking and drying mechanism 90 implements the baking and drying processing for baking and drying the extremely thin liquid film 61 of the raw material solution formed on the surface of the substrate 9, and forming, on the surface of the substrate 9, a nanofiber thin film 62 (thin film) having a film thickness thinner than that of the extremely thin liquid film 61 of the raw material solution and containing as a constituent material the nanofiber raw material (predetermined raw material) itself such as a carbon nanotube or a cellulose nanofiber contained in the dispersion, as shown in FIG. 4(b). Depending on the constituent material of the nanofiber thin film 62, the nanofiber thin film 62 can be formed as a thin film having various functionalities (barrier property, conductivity, anti-reflection, hydrophilicity, hydrophobicity).

Through the mist coating forming method by steps S1 to S3 described above, the nanofiber thin film 62 can be formed on the surface of the substrate 9. In the example described above, an example of using the nanofiber dispersion as the raw material solution 5 has been described; however, by implementing the mist coating forming method by the above-described steps S1 to S3 using the nanoparticle dispersion as the raw material solution 5, a nanoparticle thin film can be formed on the surface of the substrate 9.

In this way, in the mist coating forming apparatus of the present embodiment which implements the mist coating forming method including steps S1 to S3 shown in FIG. 3, the mist coating mechanism 70 coats the raw material solution mist 6 to form the extremely thin liquid film 61 of the raw material solution on the surface of the substrate 9 by using the nanoparticle dispersion or the nanofiber dispersion as the raw material solution 5. Then, the baking and drying mechanism 90 bakes and dries the extremely thin liquid film 61 of the raw material solution to form, on the surface of the substrate 9, the thin functional film (nanoparticle thin film or nanofiber thin film) containing as a constituent material the raw material (predetermined raw material) of the raw material solution 5.

As a result, the mist coating forming apparatus of the present embodiment can form with high uniformity, on the surface of the substrate 9, a thin film having various functionalities and containing as a constituent the raw material (nanoparticle raw material or nanofiber raw material) of the raw material solution 5 contained in the nanoparticle dispersion or the nanofiber dispersion.

In addition, since the mist coating forming apparatus of the present embodiment, which implements the above-described mist coating forming method, does not require a vacuum device, it is possible to make the apparatus simple and to reduce the initial cost and the running cost.

Next, with reference to FIG. 3, film formation verification processing of the nanofiber thin film 62 formed on the surface of the substrate 9 using the mist coating forming method by the mist coating forming apparatus of Embodiment 1 will be described.

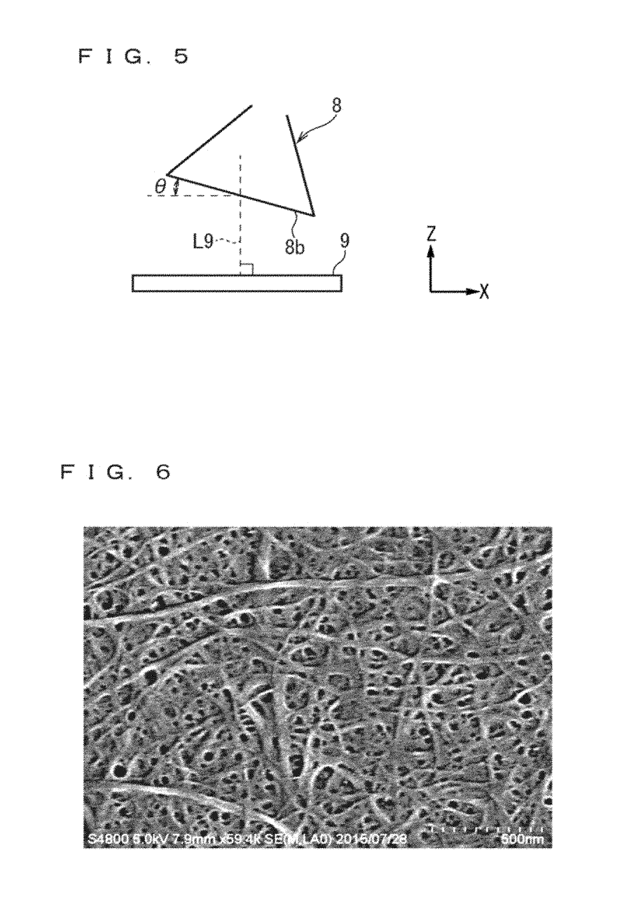

In step S4 of FIG. 3, the nanofiber thin film 62 formed on the surface of the substrate 9 was selectively observed with a SEM (Scanning Electron Microscope). FIG. 6 is a view showing an image of the nanofiber thin film 62 observed with the SEM.

As shown in FIG. 6, by implementing the mist coating forming method using the mist coating forming apparatus of the present embodiment, the nanofiber thin film 62 having a fine fiber structure could be formed.

While the present invention has been described in detail, the foregoing description is in all aspects illustrative, and the present invention is not limited thereto. It is understood that innumerable modifications not illustrated can be envisaged without departing from the scope of the present invention.

### EXPLANATION OF REFERENCE SIGNS

1: ultrasonic transducer
4: atomization container
5: raw material solution
6: raw material solution mist
8: mist coating head
8b: head bottom surface
9: substrate
10: moving stage
11: mist coating chamber
13: hot plate
14: baking-drying chamber
16: carrier gas supply part
18: mist ejection port
21: carrier gas introduction line
22: mist supply line
21b: valve
35: mist controller
37: movement controller
50: raw material solution mist-forming mechanism
70: mist coating mechanism
90: baking and drying mechanism

1. A mist coating forming apparatus comprising:
a raw material solution mist-forming mechanism configured to form a mist from a raw material solution in an atomization container by using an ultrasonic transducer to obtain a raw material solution mist in a form of droplets, said raw material solution being a nanoparticle dispersion or a nanofiber dispersion containing a predetermined raw material;
a mist coating mechanism including a mounting part on which a substrate subjected to film formation is mounted, and configured to supply said raw material solution mist to said substrate, to coat said raw material solution mist to a surface of said substrate, and to form a liquid film of the raw material solution on the surface of said substrate; and
a baking and drying mechanism configured to bake and dry said liquid film of the raw material solution formed on the surface of said substrate to form, on the surface of said substrate, a thin film containing as a constituent material said predetermined raw material contained in said liquid film of the raw material solution.

2. The mist coating forming apparatus according to claim 1, wherein said raw material solution mist-forming mechanism includes a carrier gas supply part configured to supply a carrier gas for transporting said raw material solution mist toward said mist coating mechanism.

3. The mist coating forming apparatus according to claim 1, wherein
said mist coating mechanism further includes
a mist coating head configured to eject said raw material solution mist from a mist ejection port, said mist ejection port having a slit shape in which a predetermined direction is a longitudinal direction, and
a movement controller configured to move said mounting part along a moving direction which matches a transverse direction of said mist ejection port of said mist coating head, and to variably control a moving speed of said mounting part along said moving direction.

4. A mist coating forming method comprising:
(a) a step of forming a mist from a nanoparticle dispersion or a nanofiber dispersion containing a predetermined raw material to obtain a raw material solution mist;
(b) a step of supplying said raw material solution mist to a substrate subjected to film formation and coating said raw material solution mist to a surface of said substrate to form a liquid film of a raw material solution on the surface of said substrate; and
(c) a step of baking and drying said liquid film of the raw material solution formed on the surface of said substrate to form a thin film containing said predetermined raw material on the surface of said substrate.
